(19) United States
(12) Patent Application Publication
(10) Pub. No.: US 2025/0221236 A1
(43) Pub. Date: Jul. 3, 2025

(54) DISPLAY DEVICE

(71) Applicant: LG DISPLAY CO., LTD., Seoul (KR)

(72) Inventors: Jaewoo KIM, Paju-si (KR); Kwangsoo KIM, Paju-si (KR)

(73) Assignee: LG DISPLAY CO., LTD., Seoul (KR)

(21) Appl. No.: 18/797,204

(22) Filed: Aug. 7, 2024

(30) Foreign Application Priority Data
Dec. 29, 2023 (KR) 10-2023-0196950

(51) Int. Cl. H10K 59/80

(52) U.S. Cl. CPC H10K 59/80

(57) ABSTRACT

A display device includes a display panel including at least one sensor hole, a backplate layer disposed under the display panel, and a first reinforcement member surrounding the at least one sensor hole, wherein the at least one sensor hole passes through the display panel and the backplate layer, and the first reinforcement member is disposed coplanarly with the backplate layer.

### CROSS-REFERENCE TO RELATED APPLICATION

The present application claims the priority of Korean Patent Application No. 10-2023-0196950, filed Dec. 29, 2023, which is hereby incorporated by reference in its entirety.

### BACKGROUND

### Field of the Disclosure

The present disclosure relates to a display device.

### Description of the Background

As the information society develops, various demands for display devices for displaying images are increasing, and various types of display devices such as liquid crystal display (LCD) devices and organic light emitting diode (OLED) display devices are utilized.

Among the display devices, there is an advantage in that the OLED displays as the self-luminous types have superior viewing angles and contrast ratios than the LCDs, and are lighter and thinner and have low power consumption because they do not require a separate backlight. In addition, there is an advantage in that the OLED displays may drive at a low direct current voltage, have a fast response speed, and especially low manufacturing costs.

In addition, in the case of the display device, an optical device may be embedded therein, and the optical device limits a screen design, thereby making the screen design difficult. Therefore, the display device forms a space for the optical device by forming a hole.

### SUMMARY

The present disclosure is directed to providing a display device with increased rigidity near a sensor hole.

The present disclosure is also directed to providing a display device capable of preventing cracks of a display panel.

The present disclosure is also directed to providing a display device with an expanded area of a display area.

Additional features and advantages of the disclosure will be set forth in the description which follows and in part will be apparent from the description, or may be learned by practice of the disclosure. Other advantages of the present disclosure will be realized and attained by the structure particularly pointed out in the written description and claims hereof as well as the appended drawings.

To achieve these and other advantages and in accordance with the present disclosure, as embodied and broadly described, a display device according to one aspect includes a display panel including at least one sensor hole, a backplate layer disposed under the display panel, and a first reinforcement member surrounding the at least one sensor hole, wherein the at least one sensor hole passes through the display panel and the backplate layer, and the first reinforcement member is disposed coplanarly with the backplate layer.

In another aspect of the present disclosure, a display device includes a display panel including a sensor hole and a non-display area surrounding the sensor hole, and a first reinforcement member surrounding the sensor hole and located on a different layer from the display panel, wherein the first reinforcement member overlaps the non-display area.

Detailed matters of other aspects are included in a detailed description and accompanying drawings.

The display panel of the display device according to the aspects may further include the reinforcement member disposed near at least one sensor hole. The reinforcement member may supplement the rigidity of the sensor hole by surrounding the sensor hole vulnerable to the external impact.

In addition, when the display area is located away from the sensor hole to prevent the cracks occurring from the sensor hole from being transferred to the display area, the area of the display area may be decreased. However, the display device according to the aspects may include the reinforcement member surrounding the sensor hole, thereby increasing the area of the display area.

In addition, the display device according to the aspects may increase the durability of the display device and increase the lifetime of the display device by arranging the reinforcement member near the sensor hole vulnerable to the external impact.

However, the effects obtainable from the present disclosure are not limited to the above-described effects, and other effects that are not mentioned will be able to be clearly understood by those skilled in the art to which the present disclosure pertains from the following description.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a plan view of a display device according to a first aspect;

FIG. 2 is a cross-sectional view along line A-A′ in FIG. 1;

FIG. 3 is an enlarged plan view of area Q1 in FIG. 1;

FIG. 4 is an enlarged plan view of area Q2 in FIG. 3;

FIG. 5 is a cross-sectional view along line B-B′ in FIG. 1;

FIG. 6 is a cross-sectional view along line C-C′ in FIG. 4;

FIG. 7 is a schematic view showing tensile stress of the display device according to the first aspect;

FIG. 8 is a plan view of a display device according to a second aspect;

FIG. 9 is a cross-sectional view along line D-D′ in FIG. 8;

FIG. 10 is a schematic view showing tensile stress of the display device according to the second aspect;

FIG. 11 is a plan view of a display device according to a third aspect;

FIG. 12 is a cross-sectional view along line E-E′ in FIG. 11;

FIG. 13 is a schematic view showing tensile stress of the display device according to the third aspect;

FIG. 14 is a plan view of a display device according to a fourth aspect;

FIG. 15 is a schematic view showing tensile stress of the display device according to the fourth aspect;

FIG. 16 is a schematic view showing tensile stress of a display device according to a fifth aspect;

FIG. 17 is a plan view of a display device according to a sixth aspect;

FIG. 18 is a schematic view showing tensile stress of the display device according to the sixth aspect;

FIG. 19 is a plan view of a display device according to a seventh aspect; and

FIG. 20 is a schematic view showing tensile stress of the display device according to the seventh aspect.

### DETAILED DESCRIPTION

Hereinafter, aspects will be described with reference to the accompanying drawings. In the disclosure, when a first component (or an area, a layer, a portion, or the like) is described as “on,” “connected,” or “coupled to” a second component, it means that the first component may be directly connected/coupled to the second component or a third component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the aspects. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the disclosure and does not preclude the presence or addition possibility of one or more other features, numbers, steps, operations, components, parts, or combinations thereof in advance.

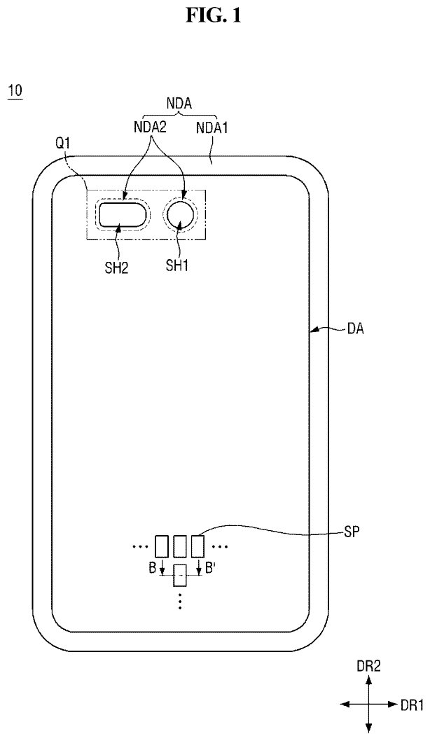

FIG. 1 is a plan view of a display device according to a first aspect.

Referring to FIG. 1, a display device 10 according to the first aspect may include an optical module and a display panel. For example, the optical module may include a sensor, and the sensor may include a camera sensor, a distance monitoring sensor, or a facial recognition sensor, but is not limited thereto.

The display panel may include a display area DA and a non-display area NDA. The display area DA may be an area in which images are displayed. For example, the display area DA may be an active area. The non-display area NDA may be located near the display area DA or may surround the display area DA. For example, the non-display area NDA may be a non-active area or a bezel area.

The display area DA in the display device 10 may include a plurality of sub-pixels SP. The sub-pixel SP may include a pixel circuit composed of a switching transistor, a driving transistor, an organic light emitting diode, and the like.

The display device 10 according to the first aspect may be an organic light emitting diode (OLED) display device, a quantum dot display device, a micro light emitting diode (micro LED) display device, or the like, but is not limited thereto.

One or more sensor holes SH1 and SH2 may be disposed in the display area DA. For example, sensors may be disposed to correspond one-to-one to the sensor holes SH1 and SH2. For example, the sensor may be a camera sensor, a distance monitoring sensor, or a facial recognition sensor, but is not limited thereto. Since the sensor may be disposed in each of the sensor holes SH1 and SH2, the non-display area NDA may be decreased, and the display area DA may be extended or widened. Products with an expanded display area DA may increase the user's screen immersion.

As shown, two sensor holes SH1 and SH2 may be provided. In this case, a camera sensor may be disposed in the first sensor hole SH1, and a distance monitoring sensor or a facial recognition sensor may be disposed in the second sensor hole SH2, but the present disclosure is not limited thereto, and the camera sensor, and the distance monitoring sensor or the facial recognition sensor may be disposed interchangeably.

For example, the number and shapes of sensor holes may be changed in any of various ways. For example, one sensor hole or three or more sensor holes may be provided. Hereinafter, an example in which the two sensor holes SH1 and SH2 are disposed in the display area DA will be mainly described.

The non-display area NDA may include a first non-display area NDA1 adjacent to the display area DA and a second non-display area NDA2 adjacent to the sensor holes SH1 and SH2. For example, the first non-display area NDA1 may be located outside the display area DA and may surround the display area DA, and the second non-display area NDA2 may be located in the display area DA and may surround each of the sensor holes SH1 and SH2.

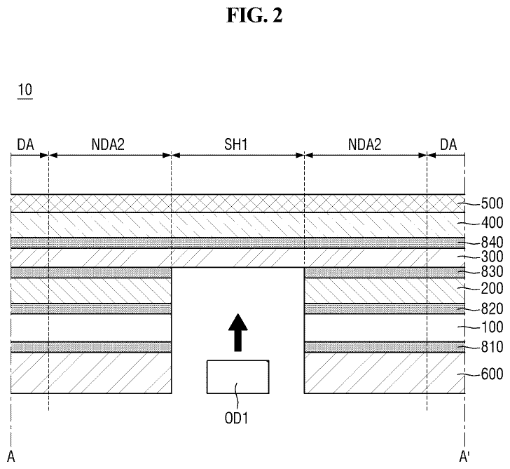

FIG. 2 is a cross-sectional view along line A-A′ in FIG. 1.

Referring to FIGS. 1 and 2, the display device 10 according to the first aspect may include a display panel 100, a polarization layer 200 disposed on the display panel 100, a cover layer 300 disposed on the polarizing layer 200, a film layer 400 disposed on the cover layer 300, a hard coating layer 500 disposed on the film layer 400, a backplate layer 600 disposed under the display panel 100, and coupling layers 810, 820, 830, and 840 coupling adjacent members 100, 200, 300, 400, and 600.

The display panel 100 may include a plurality of sub-pixels SPs disposed in the display area of a base substrate, and drivers disposed in the non-display area NDA near the display area DA to drive the sub-pixels SPs. The sub-pixels SPs may include transistors TFTs connected to the drivers through control signal lines, and a light emitting element OLED connected to the transistors TFTs. The transistors TFTs are turned on or off according to control signals applied through the control signal lines to adjust the amount of current applied to the light emitting element OLED. The light emitting element OLED may emit light with brightness corresponding to the amount of current applied through the transistors TFT. The light emitting element OLED may include a light emitting diode, but is not limited thereto. The display panel 100 may not be disposed in the first sensor hole SH1. Although FIG. 2 shows the cross-sectional shapes of the first sensor hole SH1 and areas DA and NDA2 near the first sensor hole SH1 in FIG. 1, the cross-sectional shape of the second sensor hole SH2 may also be substantially the same as the cross-sectional shape of the first sensor hole SH1.

The backplate layer 600 may be disposed under the display panel 100. The backplate layer 600 may be disposed under the display panel 100 to support the display panel 100. The backplate layer 600 may include a material capable of supporting the display panel 100. For example, the backplate layer 600 may include polyethylene terephthalate (PET), polyimide (PI), or polycarbonate (PC), but is not limited thereto. The backplate layer 600 may not be disposed in the first sensor hole SH1.

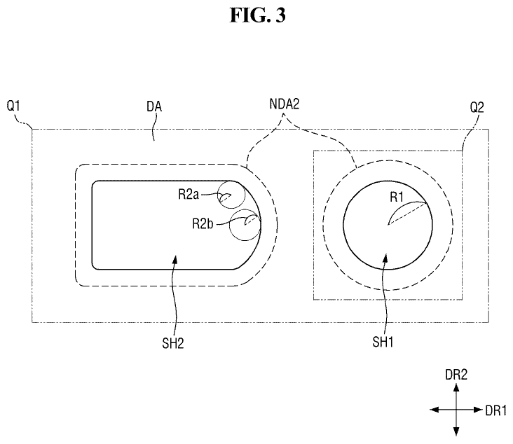

The polarization layer 200 may be disposed above the display panel 100. The polarization layer 200 may include a first phase retardation layer, a second phase retardation layer disposed on the first phase retardation layer, and a polarization layer disposed on the second phase retardation layer. In FIG. 3, the polarization layer 200 and the display panel 100 are shown as being separated from each other, but are not limited thereto, and the polarization layer 200 may be defined as being included in the display panel 100. The polarization layer 200 may not be disposed in the first sensor hole SH1.

The cover layer 300 may be disposed on the polarization layer 200. The cover layer 300 may be made of glass or a glass material including quartz. However, the cover layer 300 is not limited thereto and may be made of a plastic material.

The cover layer 300 may be disposed above the display panel 100 to protect members disposed under the cover layer 300 from the outside. A modulus of the cover layer 300 may be smaller than or equal to 70 GPa, and a thickness t3 may also be smaller than or equal to about 100 μm. However, when the thickness of the cover layer 300 is too small, the cover layer 300 cannot serve to protect the members disposed under the cover layer 300, and thus the cover layer 300 may have a thickness of at least about 20 μm or more. The cover layer 300 may be a cover layer formed by chemical reinforcement.

Meanwhile, although the cover layer 300 serves to protect the members disposed under the cover layer 300 from the outside, as described above, since the cover layer is made of a glass material, the cover layer 300 may be destroyed by an external force to generate glass fragments, and the glass fragments may shatter to the outside of the display device 10. In the first aspect, to prevent the shattering of the glass fragments generated by the destruction of the cover layer 300, the film layer 400 and the hard coating layer 500 may be further included above the cover layer 300.

The cover layer 300 may also be disposed in the first sensor hole SH1.

The film layer 400 may function to protect the cover layer 300. The film layer 400 may be a thin film sheet made of a polymer organic material. The film layer 400 may have a high transmittance of 88% or more, heat resistance of 100° C. or higher, and a coefficient of thermal expansion of 80 e-6/K or less. This is to prevent the film layer 400 from being bent or damaged in a high-temperature, high-humidity, or thermal impact environment (e.g., in 100° C.). In other words, the film layer 400 may have a low coefficient of thermal expansion and may be made of a material with thermal stability. For example, the film layer 400 may be made of polyimide (PI), (poly) norbornene, high heat-resistant polyester (PET), an epoxy, urethane, or the like. Alternatively, the film layer 400 may be made of a co-polymer. For example, the film layer 400 may be made of a copolymer bonding polymethyl methacrylate (PMMA) with special PMMA, a copolymer bonding polycarbonate (PC) with PI, a copolymer bonding PMMA with PI, or a copolymer bonding urethane. A thickness of the film layer 400 may be about 75 μm or less. However, only when the thickness t4 of the film layer 400 is about 25 μm or more, the film layer 400 may serve to protect the cover layer 300. In other words, only when the thickness t4 of the film layer 400 is about 25 μm or more, it is possible to prevent physical destruction of the cover layer 300 and prevent shattering even when the cover layer 300 is destroyed to generate glass fragments.

A modulus of the film layer 400 may be smaller than the modulus of the cover layer 300 and may be larger than a modulus of the third coupling layer 830. For example, the modulus of the film layer 400 may be in the range of 2 GPa to 8 GPa. The film layer 400 may have a modulus of 2 Gpa or more depending on the material of the film layer 400.

The film layer 400 may also be disposed in the first sensor hole SH1.

The hard coating layer 500 may be disposed on the film layer 400. The hard coating layer 500 may be formed by being coated directly on an upper surface of the film layer 400. Since the hard coating layer 500 touches a front surface of the cover layer 300, the hard coating layer 500 may be implemented as a surface protective layer with more reinforced strength, and when the hard coating layer 500 is used as the surface protective layer, the hard coating layer 500 uses a material with a high content of a resin with a relatively high hardness when cured, for example, a resin such as acrylic or an epoxy. In addition, the hard coating layer 500 may be given an anti-finger (AF) or anti-reflective (AR) function as needed, may be implemented by synthesizing a resin having these functions, or implemented by forming various patterns, for example, patterns such as moth eye.

The hard coating layer 500 may also be disposed in the first sensor hole SH1.

The coupling layers 810 to 840 may include the first coupling layer 810 coupling the backplate layer 600 with the display panel 100, the second coupling layer 820 that couples the display panel 100 with the polarization layer 200, the third coupling layer 830 that couples the polarization layer 200 with the cover layer 300, and the fourth coupling layer 840 that couples the cover layer 300 with the film layer 400.

Each of the coupling layers 810 to 840 may include an optically transparent resin (OCR) or an optically transparent adhesive (OCA).

The coupling layers 810 to 840 may not be disposed in the first sensor hole SH1. On the other hand, the fourth coupling layer 840 may be disposed in the first sensor hole SH1.

A first sensor OD1 may be disposed in the first sensor hole SH1. The first sensor OD1 may include any one of the camera sensor, the distance monitoring sensor, and the facial recognition sensor.

FIG. 3 is an enlarged plan view of area Q1 in FIG. 1.

Referring to FIG. 3, the second non-display area NDA2 may fully surround each of the sensor holes SH1 and SH2. For example, the first sensor hole SH1 may have a circular shape with one first radius of curvature R1, and the second sensor hole SH2 may have a multi-curvature shape with two or more second radii of curvature R2a and R2b. For example, the second sensor hole SH2 may have an elliptical shape. For example, an area facing the first sensor hole SH1 of the second sensor hole SH2 may have an elliptical shape and have the two or more second radii of curvature R2a and R2b. Each of the second radii of curvature R2a and R2b may be a different radius of curvature.

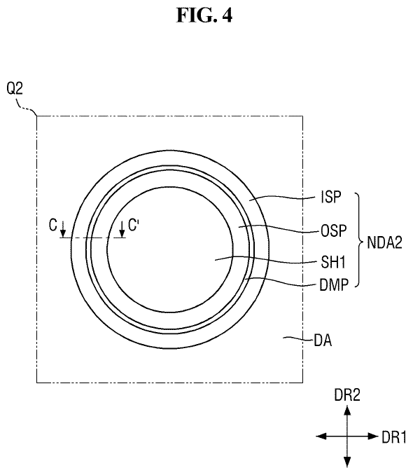

FIG. 4 is an enlarged plan view of area Q2 in FIG. 3. In FIG. 4, although only the first sensor hole SH1 and the second non-display area NDA2 near the first sensor hole SH1 are shown, the second non-display area NDA2 near the second sensor hole SH2 (see FIG. 3) may also be substantially the same as the second non-display area NDA2 near the first sensor hole SH1.

Referring to FIG. 4, the second non-display area NDA2 may include an outer separation area OSP between the first sensor hole SH1 and the display area DA, a dam area DMP between the outer separation area OSP and the display area DA, and an inner separation area ISP between the dam area DMP and the display area DA. The second non-display area NDA2 may fully surround the first sensor hole SH1. The outer separation area OSP, the dam area DMP, and the inner separation area ISP will be described in detail below.

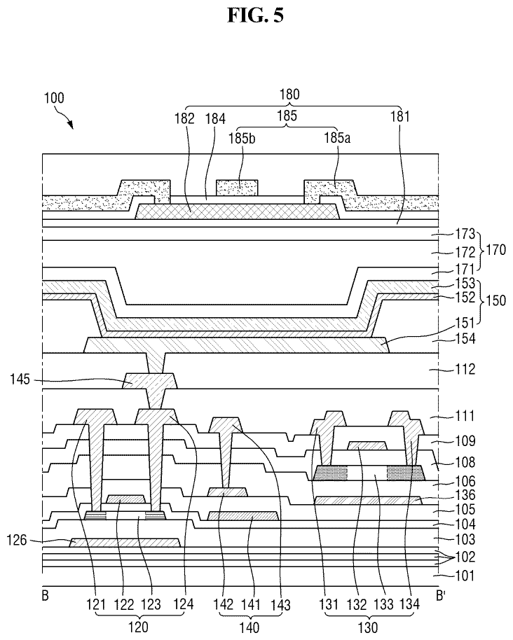

FIG. 5 is a cross-sectional view along line B-B′ in FIG. 1. Referring to FIG. 5, the display panel 100 may include a substrate 101, a buffer layer 102, a first thin film transistor 120, a second thin film transistor 130, a storage electrode 140, a light emitting part 150, an encapsulation part 170, and a touch part 180.

The substrate 101 may include one or more plastic materials. For example, the substrate 101 may be a multi-substrate including a plurality of plastic materials such as polyimide, but is not limited thereto.

The buffer layer 102 may be disposed on the substrate 101. The buffer layer 102 may minimize or delay the diffusion of moisture or oxygen permeating the substrate 101. The buffer layer 102 may be formed by alternately laminating silicon nitride (SiNx) and silicon oxide (SiOx) at least once, but is not limited thereto.

A first light blocking layer 126 may be disposed on the buffer layer 102. The first light blocking layer 126 may prevent light from being transmitted through a first semiconductor layer 123 of the first thin film transistor 120. For example, the first semiconductor layer 123 may be disposed to overlap the first light blocking layer 126. The first light blocking layer 126 may be formed of a single layer or multiple layers made of any one of molybdenum (Mo), aluminum (Al), chromium (Cr), nickel (Ni), neodymium (Nd), and copper (Cu) or an alloy thereof, but is not limited thereto.

A first insulating layer 103 may be disposed on the first light blocking layer 126. The first insulating layer 103 may prevent a short between a component of the first thin film transistor 120 and the first light blocking layer 126. The first insulating layer 103 may be made of the same material as the buffer layer 102, but is not limited thereto. For example, the first insulating layer 103 may be made of an inorganic material, such as silicon nitride (SiNx) or silicon oxide (SiOx), but is not limited thereto.

The first thin film transistor 120 may be disposed on the first insulating layer 103. The first thin film transistor 120 may include a first source electrode 121, a first gate electrode 122, a first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon or polycrystalline silicon, but is not limited thereto. The first semiconductor layer 123 may include a channel area, a source area, and a drain area.

Since the polycrystalline semiconductor layer has higher mobility than the amorphous semiconductor layer and the oxide semiconductor layer, energy consumption power may be low and reliability may be excellent. Therefore, the driving transistor may be formed as the polycrystalline semiconductor layer.

A second insulating layer 104 may be disposed on the first semiconductor layer 123. The second insulating layer 104 may be made of the same material as the first insulating layer 103 and may prevent a short between the first semiconductor layer 123 and another component of the first thin film transistor 120.

A first gate electrode 122 may be disposed on the second insulating layer 104. The first gate electrode 122 may be disposed on the second insulating layer 104 to overlap the channel area of the first semiconductor layer 123. The first gate electrode 122 may be formed of a single layer or multiple layers made of molybdenum (Mo), copper (Cu), titanium (Ti), aluminum (Al), chromium (Cr), gold (Au), nickel (Ni), neodymium (Nd), or compounds thereof. The first gate electrode 122 may be disposed together with gate lines.

A third insulating layer 105 may be disposed on the first gate electrode 122. The third insulating layer 105 may be made of the same material as the first insulating layer 103 or the second insulating layer 104.

The first source electrode 121 and the first drain electrode 124 may be disposed on the third insulating layer 105.

The first source electrode 121 and the first drain electrode 124 may be electrically connected to the first semiconductor layer 123 through contact holes. The first source electrode 121 and the first drain electrode 124 may be made of a metal material. For example, the first source electrode 121 and the first drain electrode 124 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but are not limited thereto.

The first source electrode 121 and the first drain electrode 124 may be disposed together with data lines. For example, the data line may be made of the same material as the first source electrode 121 and the first drain electrode 124 and may be formed coplanarly therewith, but is not limited thereto.

The storage electrode 140 may be disposed to be spaced apart from the first thin film transistor 120. The storage electrode 140 may include a first storage electrode 141, a second storage electrode 142, and a third storage electrode 143.

The first storage electrode 141 may be disposed coplanarly with the first gate electrode 122 and may be made of the same material as the first gate electrode 122, but is not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance. The second storage electrode 142 may be made of the same material as the first storage electrode 141, but is not limited thereto.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light blocking layer 136 may be disposed coplanarly with the second storage electrode 142.

The second light blocking layer 136 may prevent light directed to the second semiconductor layer 133 similar to the first light blocking layer 126, thereby extending the lifetime of the second thin film transistor 130. For example, the second semiconductor layer 133 may be disposed to overlap the second light blocking layer 136.

A fourth insulating layer 106 may be disposed on the second light blocking layer 136. The fourth insulating layer 106 may be made of the same material as the first insulating layer 103, the second insulating layer 104, or the third insulating layer 105, but is not limited thereto.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon or polycrystalline silicon, but is not limited thereto.

A fifth insulating layer 108 may be disposed on the second semiconductor layer 133. The fifth insulating layer 108 may be made of the same material as the first insulating layer 103, the second insulating layer 104, the third insulating layer 105, or the fourth insulating layer 106, but is not limited thereto.

A second gate electrode 132 may be disposed on the fifth insulating layer 108.

The second gate electrode 132 may be made of the same material as the first gate electrode 122. For example, the second gate electrode 132 may be formed of a single layer or multiple layers made of molybdenum (Mo), copper (Cu), titanium (Ti), aluminum (Al), chromium (Cr), gold (Au), nickel (Ni), neodymium (Nd), or compounds thereof, but is not limited thereto.

A sixth insulating layer 109 may be disposed on the second gate electrode 132. The sixth insulating layer 109 may be made of the same material as the first insulating layer 103, the second insulating layer 104, the third insulating layer 105, the fourth insulating layer 106, or the fifth insulating layer 108, but is not limited thereto.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be made of the same material as the first source electrode 121 and the first drain electrode 124 and disposed coplanarly therewith. For example, the third storage electrode 143, the second source electrode 131, and the second drain electrode 134 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but are not limited thereto.

The first thin film transistor 120 may be a driving transistor, and the second thin film transistor 130 may be a switching transistor, but are not limited thereto.

A first protective layer 111 may be disposed on the first source electrode 121 and the first drain electrode 124.

The first protective layer 111 may planarize an upper portion of the first thin film transistor 120 and protect the first thin film transistor 120. The first protective layer 111 may be made of an organic material. For example, the first protective layer 111 may be made of an organic material containing an acrylic resin, an epoxy resin, a phenolic resin, a polyamide resin, or a polyimide resin, but is not limited thereto.

A second protective layer 112 may be disposed on the first protective layer 111. The second protective layer 112 may be made of the same material as the first protective layer 111, but is not limited thereto.

A connection electrode 145 may be disposed between the first protective layer 111 and the second protective layer 112.

The connection electrode 145 may electrically connect the first thin film transistor 120 with the light emitting part 150. The connection electrode 145 may be made of the same material as the first source electrode 121 and the first drain electrode 124, but is not limited thereto.

The connection electrode 145 may be formed of a single layer or multiple layers made of any one of molybdenum (Mo), aluminum (Al), chromium (Cr), gold (Au), titanium (Ti), nickel (Ni), neodymium (Nd), and copper (Cu) or an alloy thereof, but is not limited thereto.

The light emitting part 150 may be disposed on the second protective layer 112. The light emitting part 150 may include an anode 151, an organic layer 152, and a cathode 153.

The anode 151 may be disposed on the second protective layer 112. The anode 151 may be electrically connected to the first thin film transistor 120 through a contact hole formed in the second protective layer 112. The anode 151 may be a reflective electrode that reflects light, but is not limited thereto. The anode 151 may include a metal material with high reflectivity, such as a laminated structure (Ti/Al/Ti) of aluminum (Al) and titanium (Ti), a laminated structure (ITO/Al/ITO) of aluminum (Al) and indium tin oxide (ITO), or an APC alloy, and may be formed of a single layer or multiple layers, but is not limited thereto.

The organic layer 152 may be disposed on the anode 151. The organic layer 152 may include one or more light emitting structures (or light emitting elements or elements) laminated on the anode 151 in the order or reverse order of a hole transport layer and an electron transport layer. The organic layer 152 may be an organic light emitting layer, an inorganic light emitting layer, a quantum dot light emitting layer, a micro light emitting diode, a micro mini light emitting diode, or the like, but is not limited thereto. For example, the organic layer 152 of the display panel 100 according to one aspect of the present disclosure may include the organic light emitting layer. The organic layer 152 may include a red light emitting layer, a green light emitting layer, and a blue light emitting layer.

The cathode 153 may be disposed on the organic layer 152. The cathode 153 may be a transparent electrode that transmits light, but is not limited thereto. For example, the cathode 153 may include a transparent conductive material, such as indium tin oxide (ITO) and indium zinc oxide (IZO), or a metal that transmits visible light.

The bank 154 may be disposed to expose the anode 151. The bank 154 may define an opening (or a light emitting area) of the sub-pixel and may be disposed to cover an edge portion of the anode 151. Each sub-pixel may include a red light emitting area, a green light emitting area, and a blue light emitting area. For example, the sub-pixel may be defined as a pixel, but is not limited by the term.

The encapsulation part 170 may be disposed on the bank 154 or the light emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material.

A touch buffer layer 181 may be disposed on the encapsulation part 170. For example, the touch buffer layer 181 may be disposed on the third encapsulation layer 173. The touch buffer layer 181 may be made of the same material as the buffer layer 102. A touch insulating layer 184 may be disposed on the touch buffer layer 181. The touch insulating layer 184 may prevent a short between the touch electrodes. The touch insulating layer 184 may be made of silicon oxide (SiOx), silicon nitride (SiNx), or multiple layers thereof, but is not limited thereto. A first touch electrode 185 may be disposed on the touch insulating layer 184. The first touch electrode 185 may include a 1a touch electrode 185a extending in a first direction and a 1b touch electrode 185b extending in a second direction that differs from the first direction.

A second touch electrode 182 may be disposed between the touch buffer layer 181 and the touch insulating layer 184.

The second touch electrode 182 may be electrically connected to the 1a touch electrode 185a through a contact hole formed in the touch insulating layer 184. For example, the 1a touch electrode 185a and the second touch electrode 182 may extend in the first direction.

The first touch electrode 185 and the second touch electrode 182 may include a metal material. For example, the first touch electrode 185 and the second touch electrode 182 may be made of titanium (Ti), nickel (Ni), aluminum (Al), or an alloy thereof and may be formed of a triple layer, such as titanium (Ti)/aluminum (Al)/titanium (Ti), but is not limited thereto.

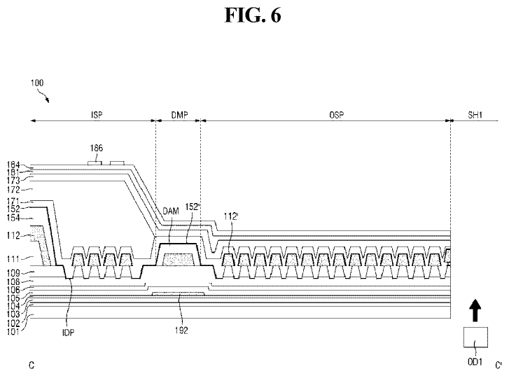

FIG. 6 is a cross-sectional view along line C-C′ in FIG. 4. FIG. 6 shows cross sections of the second non-display area NDA2 and the first sensor hole SH1.

Referring to FIGS. 1 to 6, the display panel 100 may include the substrate 101, an insulating layer disposed on the substrate 101, and a pattern 112′ disposed on the insulating layer. The pattern 112′ may be disposed coplanarly with the second protective layer 112 and may include the same material. Hereinafter, descriptions that are substantially the same as those in FIG. 3 will be given the same reference numerals, overlapping descriptions thereof will be omitted, and only parts that differ from those in FIG. 3 will be described.

Referring to FIG. 1 together, although screen immersion may be increased by maximizing the display area DA by forming the sensor holes SH1 and SH2 inside the display area DA, an end portion of the organic layer 152′ may be exposed in a process of forming the sensor holes SH1 and SH2. Here, the organic layer 152′ may be made of the same material as the organic layer 152 of the display area DA and may be formed coplanarly with the organic layer 152.

Therefore, a moisture permeable path may be formed from the end portion of the organic layer 152′ exposed through the sensor holes SH1 and SH2 to the light emitting part 150 of the display area DA. The display panel 100 may block moisture, oxygen, and foreign substance that may move along the moisture permeable path by providing a disconnection structure of the organic layer 152′ or the like.

A dam DAM may be disposed in the dam area DMP.

The dam DAM may be made of the same material as the second protective layer 112 and the bank 154, and to reduce the area of the second non-display area NA2, only one dam DAM may be disposed, but the present disclosure is not limited thereto. In addition, the organic layer 152′ may be disposed to cover the dam DAM. The dam DAM may more effectively prevent the permeation of moisture and oxygen by increasing a distance of the moisture and oxygen permeation path.

To delay and block the permeation of moisture introduced from the outside through the exposed end portion of the organic layer 152′ and prevent damage to the display panel 100 due to foreign substance, the pattern 112′ may be disposed throughout the inner separation area ISP and the outer separation area OSP.

The touch buffer layer 181 may be formed throughout the display area DA and the second non-display area NDA2. For example, the touch buffer layer 181 may be formed throughout the inner separation area ISP, the dam area DMP, and the outer separation area OSP.

A hole crack detection part 186 may be formed on the touch buffer layer 181. For example, the hole crack detection part 186 may be formed in the second non-display area NDA2. For example, the hole crack detection part 186 may be formed in the inner separation area ISP, but is not limited thereto.

In the display panel 100, the sensor holes SH1 and SH2 may be formed in the components disposed on the substrate 101 in addition to the substrate 101. The sensor holes SH1 and SH2 may expose the components disposed on the substrate 101 in addition to the substrate 101. The components disposed on the substrate 101 in addition to the exposed substrate 101 may be exposed to physical or chemical damage. For example, cracks may occur in areas corresponding to the sensor holes SH1 and SH2 of the display panel 100. For example, the hole crack detection part 186 may be exposed to a physical impact or the like in the areas corresponding to the sensor holes SH1 and SH2.

When the hole crack detection part 186 is disconnected by the cracks, the hole crack detection part 186 may not transmit electrical signals and thus may detect the cracks. The hole crack detection part 186 may be disposed coplanarly with the first touch electrode 185 and made of the same material. The hole crack detection part 186 may be formed to surround the sensor holes SH1 and SH2. For example, the hole crack detection part 186 may be formed to have a curved surface corresponding to the sensor holes SH1 and SH2. For example, the hole crack detection part 186 may be formed in a shape of two circles, but is not limited thereto. The hole crack detection part 186 may be formed in the inner separation area ISP. For example, the hole crack detection part 186 may be formed between the display area DA and the dam DAM, for example, formed to surround the hole crack detection part 186, but is not limited thereto.

A fourth metal layer 192 may be formed in an area that overlaps the dam DAM. The fourth metal layer 192 may be formed coplanarly with the first gate electrode 122 and made of the same material as the first gate electrode 122. For example, the fourth metal layer 192 may be formed on the substrate 101. The fourth metal layer 192 may be an alignment mark required for the process of forming the sensor holes SH1 and SH2, but is not limited thereto.

The pattern 112′ may be formed on the fifth insulating layer 108 and the sixth insulating layer 109. A plurality of patterns 112′ may be provided. The plurality of patterns 112′ may be spaced apart from each other. The pattern 112′ may be disposed coplanarly with the second protective layer 112. In the inner separation area ISP and the outer separation area OSP, the sixth insulating layer 109 may be etched. The pattern 112′ may be disposed on a non-etched area of the sixth insulating layer 109. The pattern 112′ may not be disposed in an etched area of the sixth insulating layer 109. For example, the organic layer 152′ may be disconnected by the pattern 112′. The organic layer 152′ disconnected by the pattern 112′ may be disposed on the fifth insulating layer 108 and the pattern 112′. The organic layer 152′ disposed on the pattern 112′ and the organic layer 152′ disposed on the fifth insulating layer 108 may be physically separated (spaced apart from) each other. Therefore, it is possible to block the moisture and foreign substance introduced from the outside through the exposed end portion of the organic layer 152′, thereby preventing damage to the display panel 100.

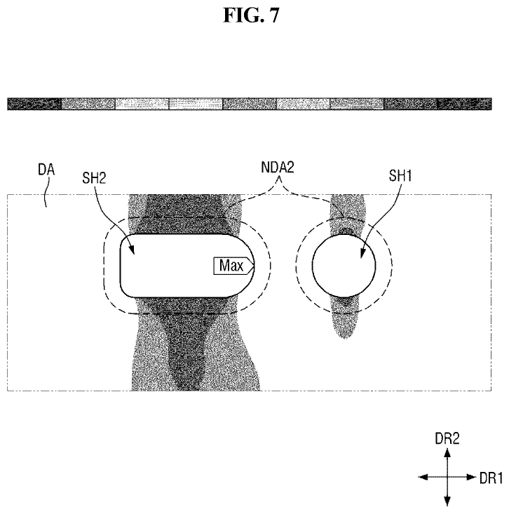

FIG. 7 is a schematic view showing tensile stress of the display device according to the first aspect. FIG. 7 shows the stress occurring in the sensor holes SH1 and SH2 when a tensile stress of about 2 MPa is applied to each of one side and the other side of the display device according to the first aspect in the second direction DR2. A tensile stress of 2 MPa is applied for 1 second.

Referring to FIGS. 1 to 7, the sensor holes SH1 and SH2 of the display device 10 according to the first aspect may be very vulnerable to an external impact or an external pressure. In particular, when a predetermined amount of impact or pressure is applied to the sensor holes SH1 and SH2, cracks may occur from the display panel 100 adjacent to the sensor holes SH1 and SH2. As shown in FIG. 7, when the tensile stress is applied to the one side and the other side of the display device according to the first aspect in a second direction DR2, it was confirmed that the maximum stress value Max of about 191 MPa was shown in an area facing the first sensor hole SH1 of the second sensor hole SH2. As described above with reference to FIG. 3, the area facing the first sensor hole SH1 of the second sensor hole SH2 is an area having an elliptical shape with multiple curvatures R2a and R2b. Next, areas with high stress were shown at an end portion of the other side of the second sensor hole SH2 in the first direction DR1 and end portions of one side and the other side of the first sensor hole SH1 in the first direction DR1. The reason why a large amount of stress occurred at the end portions of the sensor holes SH1 and SH2 in the first direction DR1 is that the tensile stress was applied to each of the one side and the other side of the display device 10 in the second direction DR2, and the reason why the largest stress occurred at the end portion of the one side of the second sensor hole SH2 in the first direction DR1 is that the end portion of the one side of the second sensor hole SH2 in the first direction DR1 has the multiple curvatures R2a and R2b.

According to the display device 10 according to the first aspect, each of the sensor holes SH1 and SH2 with weak rigidity may be exposed to an external impact, cracks may occur in the display panel 100 near the sensor holes SH1 and SH2 when an impact or pressure at a predetermined intensity or more is applied to the sensor holes SH1 and SH2, and when the cracks are transferred to the display area DA along the display panel 100, it may cause physical damage to, display defects, or the like of the display panel 100.

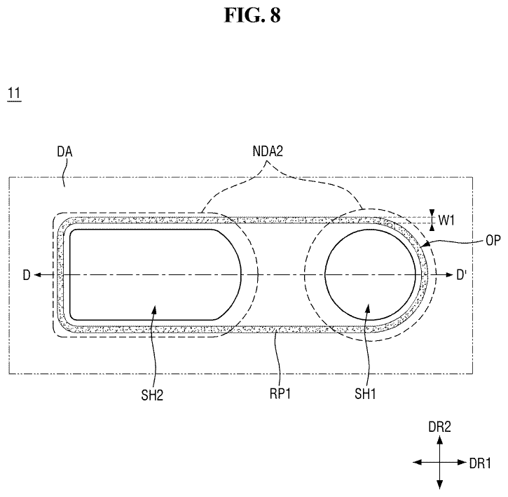

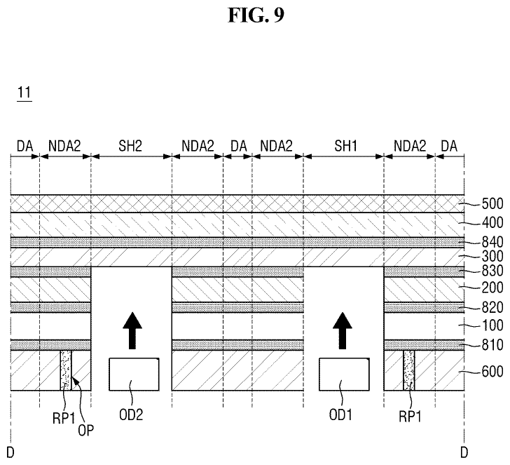

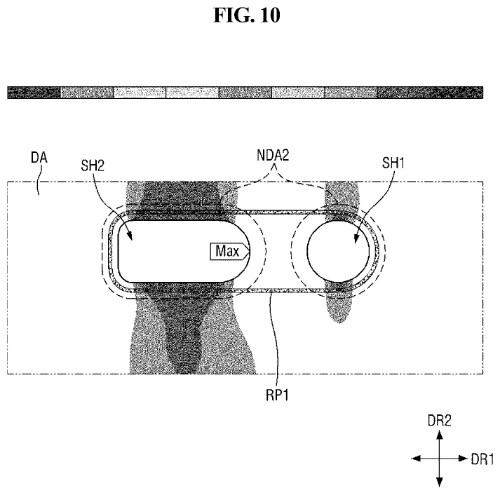

FIG. 8 is a plan view of a display device according to a second aspect. FIG. 9 is a cross-sectional view along line D-D′ in FIG. 8. FIG. 10 is a schematic view showing tensile stress of the display device according to the second aspect. FIG. 10 shows the stress occurring in the sensor holes SH1 and SH2 when a tensile stress of about 2 MPa is applied to each of one side and the other side of the display device according to the second aspect in the second direction DR2. A tensile stress of 2 MPa is applied for 1 second.

Referring to FIGS. 8 to 10, a display device 11 according to the second aspect differs from the display device 10 according to FIGS. 1 to 6 in that it further includes a first reinforcement member RP1.

The first reinforcement member RP1 may surround the first sensor hole SH1 and the second sensor hole SH2 in a plan view. The first reinforcement member RP1 may fully surround the first sensor hole SH1 and the second sensor hole SH2 in a plan view. The first reinforcement member RP1 may have a closed loop shape. The first reinforcement member RP1 may be disposed in the second non-display area NDA2 near each of the sensor holes SH1 and SH2 and may also be disposed in the display area DA between the sensor holes SH1 and SH2. Sensors OD1 and OD2 may be disposed in the sensor holes SH1 and SH2, respectively. The first reinforcement member RP1 may include a first portion located at one sides of the sensor holes SH1 and SH2 in the second direction DR2 and extending in the first direction DR1, a second portion located at the other sides of the sensor holes SH1 and SH2 in the second direction DR2 and facing the first portion, a third portion located at the one side of the first sensor hole SH1 in the first direction DR1 and extending in the second direction DR2, and a fourth portion located at the other side of the second sensor hole SH2 in the first direction DR1 and extending in the second direction DR2. The first reinforcement member RP1 may have a first width W1.

The first reinforcement member RP1 may be disposed coplanarly with the backplate layer 600. The backplate layer 600 may have an open portion OP in the second non-display area NDA2. The first reinforcement member RP1 may be disposed in the open portion OP. The first reinforcement member RP1 may have the same thickness as the backplate layer 600, but is not limited thereto.

The first reinforcement member RP1 may be disposed to surround the first sensor hole SH1 and the second sensor hole SH2 in a plan view, thereby supplementing the rigidity of the sensor holes SH1 and SH2 vulnerable to an external impact. To this end, a strength of the first reinforcement member RP1 may be greater than a strength of each of the display panel 100 and the backplate layer 600. For example, the first reinforcement member RP1 may include a metal, but the material is not limited as long as it is a material that has a greater strength than the display panel 100 and the backplate layer 600.

The first reinforcement member RP1 may overlap at least one of the outer separation area OSP, the dam area DMP, and the inner separation area ISP in FIG. 6.

As shown in FIG. 10, when the tensile stress is applied to the one side and the other side of the display device according to the second aspect in the second direction DR2, like the display device according to the first aspect of FIG. 7, it was confirmed that the maximum stress value Max of about 191 MPa was shown in an area facing the first sensor hole SH1 of the second sensor hole SH2. In FIG. 10, the reason why the maximum stress value Max is the same even though the first reinforcement member RP1 is disposed is that the first reinforcement member RP1 is only disposed to surround the first sensor hole SH1 and the second sensor hole SH2 and is not disposed near the end portion (elliptical shape) of the one side of the second sensor hole SH2 in the first direction DR1, which is the most vulnerable portion to an external impact.

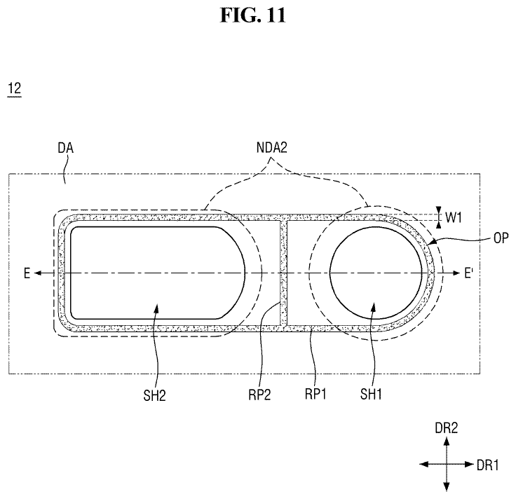

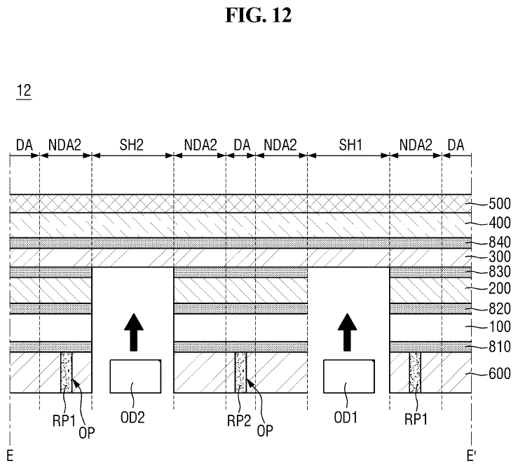

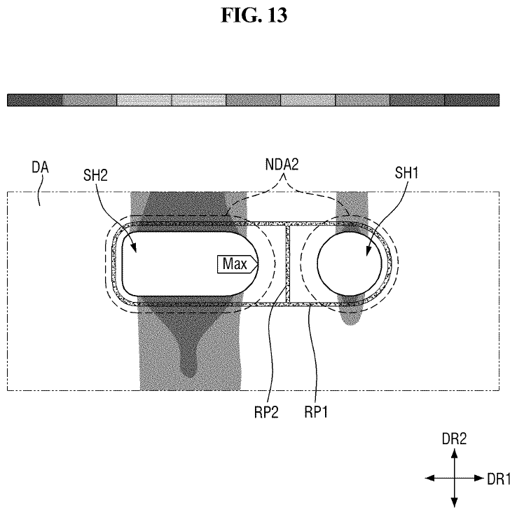

FIG. 11 is a plan view of a display device according to a third aspect. FIG. 12 is a cross-sectional view along line E-E′ in FIG. 11. FIG. 13 is a schematic view showing tensile stress of the display device according to the third aspect. FIG. 13 shows the stress occurring in the sensor holes SH1 and SH2 when a tensile stress of about 2 MPa is applied to each of one side and the other side of the display device according to the third aspect in the second direction DR2. A tensile stress of 2 MPa is applied for 1 second.

Referring to FIGS. 11 to 13, a display device 12 according to the third aspect differs from the display device 11 according to FIGS. 8 to 10 in that it further includes a second reinforcement member RP2.

The second reinforcement member RP2 may surround the first sensor hole SH1 and the second sensor hole SH2 in a plan view. The second reinforcement member RP2 may include a first portion located at one sides of the sensor holes SH1 and SH2 in the second direction DR2 and extending in the first direction DR1, a second portion located at the other sides of the sensor holes SH1 and SH2 in the second direction DR2 and facing the first portion, a third portion located at the one side of the first sensor hole SH1 in the first direction DR1 and extending in the second direction DR2, and a fourth portion located at the other side of the second sensor hole SH2 in the first direction DR1 and extending in the second direction DR2.

The second reinforcement member RP2 may extend in the second direction DR2 to be connected to each of the first portion and the second portion of the first reinforcement member RP1. An end portion of one side of the second reinforcement member RP2 in the second direction DR2 may be connected to the first portion of the first reinforcement RP1, and an end portion of the other side of the second reinforcement member RP2 in the second direction DR2 may be connected to the second portion of the first reinforcement RP1.

The second reinforcement member RP2 may include the same material as the first reinforcement member RP1.

The second reinforcement member RP2 may be disposed coplanarly with the first reinforcement member RP1 and disposed coplanarly with the backplate layer 600. The backplate layer 600 may further have an open portion OP in the display area DA between the sensor holes SH1 and SH2. The second reinforcement member RP2 may be disposed in the open portion OP of the display area DA between the sensor holes SH1 and SH2. The second reinforcement member RP2 may have the same thickness as the backplate layer 600, but is not limited thereto.

A width of the second reinforcement member RP2 in the first direction DR1 may be the same as a width of the first reinforcement member RP1, but is not limited thereto.

As shown in FIG. 13, when the tensile stress is applied to the one side and the other side of the display device according to the third aspect in the second direction DR2, like the display device according to the second aspect of FIG. 10, it was confirmed that the maximum stress value Max was shown in an area facing the first sensor hole SH1 of the second sensor hole SH2. The stress was confirmed to be about 179 MPa. As described above, the first reinforcement member RP1 is only disposed to surround the first sensor hole SH1 and the second sensor hole SH2 and is not disposed near the end portion (elliptical shape) of the one side of the second sensor hole SH2 in the first direction DR1, which is the most vulnerable portion to an external impact. On the other hand, the display device 12 further includes the second reinforcement member RP2 extending in the second direction DR2 to be connected to each of the first portion and the second portion of the first reinforcement member RP1, and thus the maximum stress value Max in the area facing the first sensor hole SH1 of the second sensor hole SH2 was reduced by about 6% compared to the display device 10 of FIGS. 1 to 7.

In other words, since the display device 12 according to the third aspect further includes the second reinforcement member RP2 disposed near the end portion (elliptical shape) of the one side of the second sensor hole SH2 in the first direction DR1, which is the most vulnerable portion to an external impact, it is possible to supplement the rigidity of the sensor holes SH1 and SH2 and prevent the occurrence of cracks in the display panel 100 near the sensor holes SH1 and SH2.

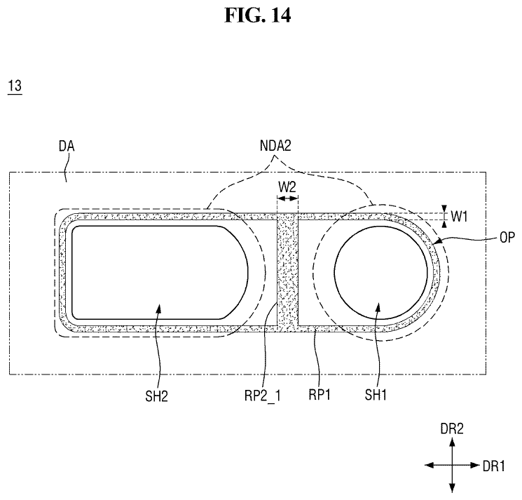

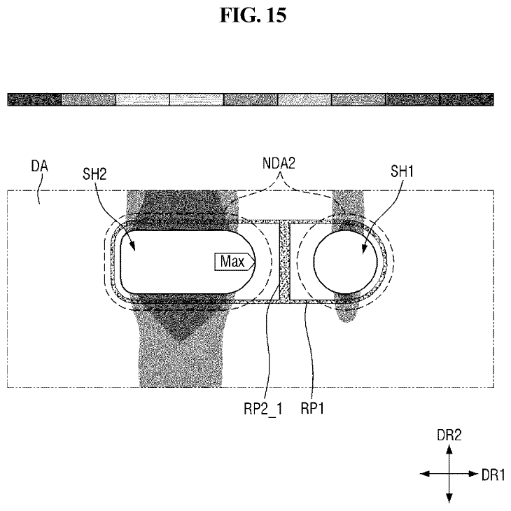

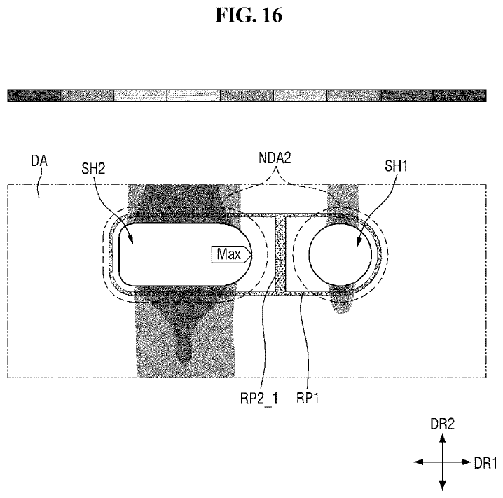

FIG. 14 is a plan view of a display device according to a fourth aspect. FIG. 15 is a schematic view showing tensile stress of the display device according to the fourth aspect. FIG. 16 is a schematic view showing tensile stress of a display device according to a fifth aspect. FIGS. 15 and 16 each show the stress occurring in the sensor holes SH1 and SH2 when a tensile stress of about 2 MPa is applied to each of one side and the other side of each of the display devices according to the fourth and fifth aspects in the second direction DR2. A tensile stress of 2 MPa is applied for 1 second.

First, referring to FIGS. 14 to 16, a display device 13 according to the fourth aspect differs from the display device 12 according to FIGS. 10 to 13 in that a width W2 of a second reinforcement member RP2_1 is greater than the width W1 of the first reinforcement member RP1.

The second reinforcement member RP2_1 may surround the first sensor hole SH1 and the second sensor hole SH2 in a plan view. The second reinforcement member RP2_1 may include a first portion located at one sides of the sensor holes SH1 and SH2 in the second direction DR2 and extending in the first direction DR1, a second portion located at the other sides of the sensor holes SH1 and SH2 in the second direction DR2 and facing the first portion, a third portion located at the one side of the first sensor hole SH1 in the first direction DR1 and extending in the second direction DR2, and a fourth portion located at the other side of the second sensor hole SH2 in the first direction DR1 and extending in the second direction DR2.

The second reinforcement member RP2_1 may extend in the second direction DR2 to be connected to each of the first portion and the second portion of the first reinforcement member RP1. An end portion of one side of the second reinforcement member RP2 in the second direction DR2 may be connected to the first portion of the first reinforcement RP1, and an end portion of the other side of the second reinforcement member RP2 in the second direction DR2 may be connected to the second portion of the first reinforcement RP1.

The second reinforcement member RP2_1 may include the same material as the first reinforcement member RP1.

The second reinforcement member RP2_1 may be disposed coplanarly with the first reinforcement member RP1 and disposed coplanarly with the backplate layer 600. The backplate layer 600 may further have an open portion OP in the display area DA between the sensor holes SH1 and SH2. The second reinforcement member RP2_1 may be disposed in the open portion OP of the display area DA between the sensor holes SH1 and SH2. The second reinforcement member RP2_1 may have the same thickness as the backplate layer 600, but is not limited thereto.

The width W2 of the second reinforcement member RP2_1 in the first direction DR1 may be greater than the width W1 of the first reinforcement member RP1.

As shown in FIG. 15, when the tensile stress is applied to the one side and the other side of the display device according to the fourth aspect in the second direction DR2, unlike the display device according to the third aspect of FIG. 13, it was confirmed that the maximum stress value Max was shown at the end portion of the other side of the second sensor hole SH2 in the first direction DR1. The stress was confirmed to be about 161 MPa. Since the display device 13 further includes the second reinforcement member RP2_1 extending in the second direction DR2 to be connected to each of the first portion and the second portion of the first reinforcement member RP1 and is designed to have the width W2 of the second reinforcement member RP2_1 that is greater than the width W1 of the first reinforcement member RP1, the stress occurring in the area facing the first sensor hole SH1 of the second sensor hole SH2 may be greatly reduced. The maximum stress value Max of the display device according to the fourth aspect was reduced by about 16% compared to the display device 10 of FIGS. 1 to 7.

In other words, since the display device 13 according to the fourth aspect further includes the second reinforcement member RP2_1 disposed near the end portion (elliptical shape) of the one side of the second sensor hole SH2 in the first direction DR1, which is the most vulnerable portion to an external impact, and having a greater width than the first reinforcement member RP1, it is possible to supplement the rigidity of the sensor holes SH1 and SH2 and prevent the occurrence of cracks in the display panel 100 near the sensor holes SH1 and SH2.

The display device according to the fifth aspect according to FIG. 16 differs from the display device 13 according to the fourth aspect in that the reinforcement members RP1 and RP2_1 include a graphite. The graphite may be a material that has a lower strength than the metal of the reinforcement members RP1 and RP2_1 of the display device 13 of FIG. 14, but has a better heat dissipation function.

As shown in FIGS. 14 and 16, when the tensile stress is applied to one side and the other side of the display device according to the fifth aspect in the second direction DR2, a strength of the graphite is lower than that of the metal (but higher than those of the backplate layer 600 and the display panel 100) even when the second reinforcement member RP2_1 has the sufficient width W2, unlike the display device according to the fourth aspect of FIG. 15, the maximum stress value Max is shown at the end portion of the one side of the second sensor hole SH2 in the first direction DR1. The stress was confirmed to be about 182 MPa.

The maximum stress value Max of the display device according to the fifth aspect was reduced by about 5% compared to the display device 10 of FIGS. 1 to 7.

However, in the display device according to the present aspect, there is an advantage in that heat resistance near the sensor holes SH1 and SH2 may be reinforced by applying graphite to the second reinforcement member RP2_1.

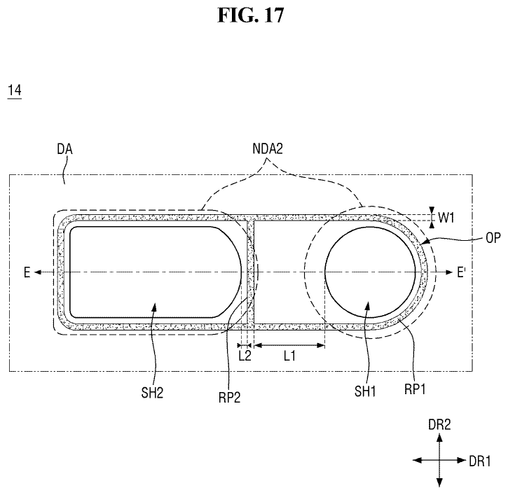

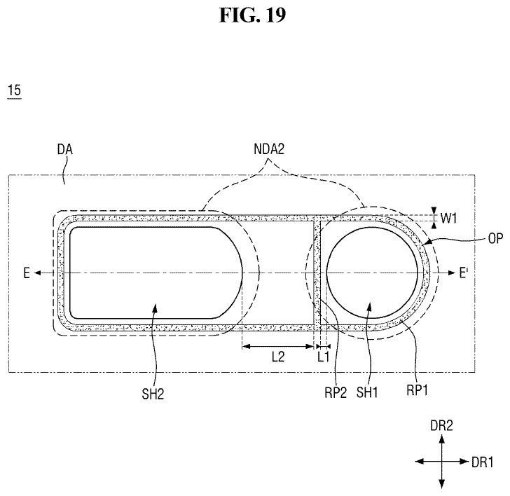

To improve the heat resistance or heat dissipation function of the display device, the application of graphite to the reinforcement member may be applied to the aspects according to FIGS. 8 and 11 in the same manner and may also be applied to aspects according to FIGS. 17 and 19, which will be described below.

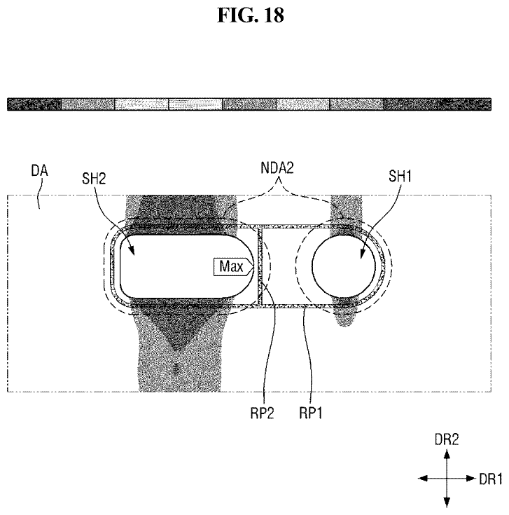

FIG. 17 is a plan view of a display device according to a sixth aspect. FIG. 18 is a schematic view showing tensile stress of the display device according to the sixth aspect.

Referring to FIGS. 17 and 18, a display device 14 according to the sixth aspect differs from the display device 11 according to FIGS. 11 to 13 in that the second reinforcement member RP2 is located closer to the second sensor hole SH2 than the first sensor hole SH1.

For example, a distance L1 between the second reinforcement member RP2 and the first sensor hole SH1 may be larger than a distance L2 between the second reinforcement member RP2 and the second sensor hole SH2. Conversely, the distance L2 between the second reinforcement member RP2 and the second sensor hole SH2 may be smaller than the distance L1 between the second reinforcement member RP2 and the first sensor hole SH1.

As shown in FIG. 18, when the tensile stress is applied to the one side and the other side of the display device according to the sixth aspect in the second direction DR2, unlike the display device according to the third aspect of FIG. 13, it was confirmed that the maximum stress value Max was shown at the end portion of the other side of the second sensor hole SH2 in the first direction DR1. The stress was confirmed to be about 170 MPa. Since the second reinforcement member RP2 of the display device 14 may be disposed closer to the second sensor hole SH2 than the first sensor hole SH1, it is possible to greatly reduce the stress occurring in the area facing the first sensor hole SH1 of the second sensor hole SH2. The maximum stress value Max of the display device according to the sixth aspect was reduced by about 11% compared to the display device 10 of FIGS. 1 to 7.

In other words, since the display device 14 according to the sixth aspect further includes the second reinforcement member RP2 disposed near the end portion (elliptical shape) of the one side of the second sensor hole SH2 in the first direction DR1, which is the most vulnerable portion to an external impact, it is possible to supplement the rigidity of the sensor holes SH1 and SH2 and prevent the occurrence of cracks in the display panel 100 near the sensor holes SH1 and SH2.

The structure of locating the second reinforcement member closer to the second sensor hole SH2 than to the first sensor hole SH1 may also be applied to the display device 13 of FIG. 14 and the display device of FIG. 16 in the same manner.

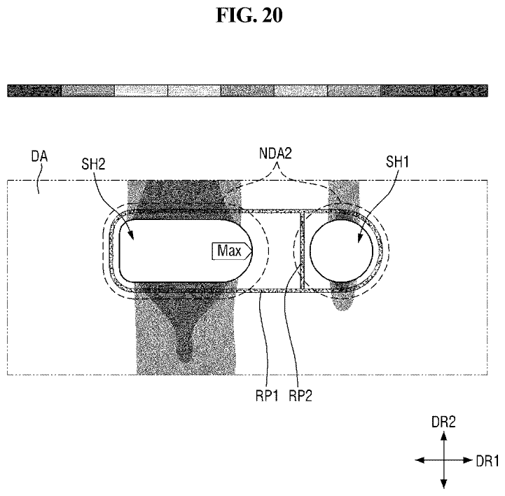

FIG. 19 is a plan view of a display device according to a seventh aspect. FIG. 20 is a schematic view showing tensile stress of the display device according to the seventh aspect.

Referring to FIGS. 19 and 20, a display device 15 according to the seventh aspect differs from the display device 14 according to FIGS. 17 and 18 in that the second reinforcement member RP2 is located further away from the second sensor hole SH2 than the first sensor hole SH1.

For example, the distance L1 between the second reinforcement member RP2 and the first sensor hole SH1 may be smaller than the distance L2 between the second reinforcement member RP2 and the second sensor hole SH2. Conversely, the distance L2 between the second reinforcement member RP2 and the second sensor hole SH2 may be larger than the distance L1 between the second reinforcement member RP2 and the first sensor hole SH1.

As shown in FIG. 20, when the tensile stress is applied to one side and the other side of the display device according to the seventh aspect in the second direction DR2, unlike the display device according to the sixth aspect of FIG. 18, the maximum stress value Max is shown at the end portion of one side of the second sensor hole SH2 in the first direction DR1. The stress was confirmed to be about 186 MPa. The second reinforcement member RP2 of the display device 15 may be disposed further away from the second sensor hole SH2 than the first sensor hole SH1. As described above, the greatest stress occurs in the area facing the first sensor hole SH1 of the second sensor hole SH2, and unlike the display device 14 according to the sixth aspect, since the second reinforcement member RP2 is disposed further away from the second sensor hole SH2, the stress reduction effects of the sensor holes SH1 and SH2 was insufficient compared to the display device 14 according to the sixth aspect.

However, the maximum stress value Max of the display device according to the seventh aspect was reduced by about 3% compared to the display device 10 of FIGS. 1 to 7.

The display devices according to some aspects include a display panel including at least one sensor hole, a backplate layer disposed under the display panel, and a first reinforcement member surrounding the at least one sensor hole, in which the at least one sensor hole passes through the display panel and the backplate layer, and the first reinforcement member is disposed coplanarly with the backplate layer.

The backplate layer may include an open portion surrounding the at least one sensor hole, and the first reinforcement member may be disposed in the open portion.

The at least one sensor hole may include a first sensor hole and a second sensor hole.

The first reinforcement member may form a closed loop and fully surround the first sensor hole and the second sensor hole.

The display device may further include a second reinforcement member disposed coplanarly with the first reinforcement member, in which the second reinforcement member may extend toward a space between the first sensor hole and the second sensor hole and may be directly connected to the first reinforcement member.

The first sensor hole and the second sensor hole may have different shapes.

The first sensor hole may have one radius of curvature, and the second sensor hole may have two or more radii of curvature.

The first sensor hole may have a circular shape, and the second sensor hole may have an elliptical shape.

The second reinforcement member may be located closer to the second sensor hole than the first sensor hole.

A width of the second reinforcement member may be greater than a width of the first reinforcement member.

A strength of the first reinforcement member may be greater than a strength of the backplate layer.

The first reinforcement member may include a metal.

The first reinforcement member may include a graphite.

Display devices according to some aspects include a display panel including a sensor hole and a non-display area surrounding the sensor hole, and a first reinforcement member surrounding the sensor hole and located on a different layer from the display panel, in which the first reinforcement member overlaps the non-display area.

The non-display area may include an inner separation area between the display area and the sensor hole, a dam area between the inner separation area and the sensor hole, and an outer separation area between the dam area and the sensor hole.

The first reinforcement member may overlap the outer separation area.

The display area may include an organic layer, and the organic layer may be separated from each of the inner separation area and the outer separation area.

The display device may further include a backplate layer disposed under the display panel, and the sensor hole may pass through the display panel and the backplate layer.

The first reinforcement member may be disposed coplanarly with the backplate layer.

The display device may further include a cover layer disposed on the display panel, and the cover layer may overlap the sensor hole.

Although the aspects have been described above with reference to the accompanying drawings, those skilled in the art to which the present disclosure pertains will be able to understand that the above-described technical configuration may be carried out in other specific forms without changing the technical spirit or essential features thereof. Therefore, it should be understood that the above-described aspects are illustrative and not restrictive in all respects. In addition, the scope of the aspects is indicated by the claims to be described below rather than the detailed description. In addition, the meaning and scope of the claims and all changed or modified forms derived from the equivalent concept thereof should be construed as being included in the scope of the aspects.

What is claimed is:

1. A display device comprising:
a display panel including at least one sensor hole;
a backplate layer disposed under the display panel; and
a first reinforcement member surrounding the at least one sensor hole, wherein the at least one sensor hole passes through the display panel and the backplate layer, and
wherein the first reinforcement member is disposed coplanarly with the backplate layer.

2. The display device of claim 1, wherein the backplate layer includes an open portion surrounding the at least one sensor hole, and the first reinforcement member is disposed in the open portion.

3. The display device of claim 1, wherein the at least one sensor hole includes a first sensor hole and a second sensor hole.

4. The display device of claim 3, wherein the first reinforcement member forms a closed loop and fully surrounds the first sensor hole and the second sensor hole.

5. The display device of claim 4, further comprising a second reinforcement member disposed coplanarly with the first reinforcement member, wherein the second reinforcement member extends toward a space between the first sensor hole and the second sensor hole and is directly connected to the first reinforcement member.

6. The display device of claim 5, wherein the first sensor hole and the second sensor hole have different shapes.

7. The display device of claim 6, wherein the first sensor hole has one radius of curvature, and the second sensor hole has two or more radii of curvature.

8. The display device of claim 7, wherein the first sensor hole has a circular shape, and the second sensor hole has an elliptical shape.

9. The display device of claim 7, wherein the second reinforcement member is located closer to the second sensor hole than the first sensor hole.

10. The display device of claim 5, wherein a width of the second reinforcement member is greater than a width of the first reinforcement member.

11. The display device of claim 1, wherein the first reinforcement member has a strength greater than a strength of the backplate layer.

12. The display device of claim 11, wherein the first reinforcement member includes a metal.

13. The display device of claim 11, wherein the first reinforcement member includes a graphite.

14. A display device comprising:
a display panel including a sensor hole, and a non-display area surrounding the sensor hole; and
a first reinforcement member surrounding the sensor hole and located on a different layer from the display panel,
wherein the first reinforcement member overlaps the non-display area.

15. The display device of claim 14, wherein the non-display area includes an inner separation area between the display area and the sensor hole, a dam area between the inner separation area and the sensor hole, and an outer separation area between the dam area and the sensor hole.

16. The display device of claim 15, wherein the first reinforcement member overlaps the outer separation area.

17. The display device of claim 15, wherein the display area includes an organic layer, and the organic layer is separated from each of the inner separation area and the outer separation area.

18. The display device of claim 14, further comprising a backplate layer disposed under the display panel,
wherein the sensor hole passes through the display panel and the backplate layer.

19. The display device of claim 18, wherein the first reinforcement member is disposed coplanarly with the backplate layer.

20. The display device of claim 18, further comprising a cover layer disposed on the display panel,
wherein the cover layer overlaps the sensor hole.
